(19) United States
(12) Patent Application Publication
(10) Pub. No.: US 2008/0210979 A1
(43) Pub. Date: Sep. 4, 2008

(54) SEMICONDUCTOR INTEGRATED CIRCUIT AND METHOD FOR DESIGNING THE SAME

(75) Inventor: Rika SUWAKI, Hachioji (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/962,263

(22) Filed: Dec. 21, 2007

(30) Foreign Application Priority Data
Dec. 27, 2006 (JP) 2006-351484
Oct. 31, 2007 (JP) 2007-282646

(51) Int. Cl. H01L 27/10

(52) U.S. Cl. 257/203; 257/E27.06

(57) ABSTRACT

A semiconductor integrated circuit, including: a semiconductor chip; an internal integrated circuit area formed at a center side of the semiconductor chip; and an I/O area formed at a peripheral side of the semiconductor chip except where the internal integrated circuit area exists, the I/O area having a first power supply cell placed at a predetermined position therein. In a case in which an empty area adjacent to the first power supply cell exists, a second power supply cell is inserted therein and the first power supply cell and the second power supply cell are electrically connected with each other by a first wiring pattern added.

The entire disclosure of Japanese Patent Application Nos: 2006-351484, filed Dec. 27, 2006 and 2007-282646, filed Oct. 31, 2007 are expressly incorporated by reference herein.

### BACKGROUND OF THE INVENTION

1. Technical Field

The present invention relates to a semiconductor integrated circuit (LSI), and to a method for designing the same.

2. Related Art

In recent semiconductor integrated circuits, there has been seen the trend to finer process or operation voltage drop associated with lower electrical consumption. Further, the wiring resistance has been increasingly larger. As a result, a problem has arisen in that the voltage drop occurs due to the wiring pattern.

Specifically, the voltage level of the voltage provided from outside to a semiconductor integrated circuit disadvantageously drops at the center portion of an internal integrated circuit because of electrical consumption or power bus resistance due to the operation of the internal integrated circuit. Therefore, in order to prevent such the drop of the voltage level, the power enhancement must be achieved.

Various measures with the purpose of such the power enhancement have been known in related art, such as the increased number of power supply wirings or power supply pins within internal integrated circuits (circuits of core areas).

Further, JP-A-2000-20576 or JP-A-2002-31392910 discloses the invention, according to which the power enhancement of a semiconductor integrated circuit is to be achieved.

The invention disclosed in the JP-A-2000-20576 is as follows: After the automated placement and routing, the consumption current is calculated based on the operation frequency of functional cells and the actual output capacitance of the functional cells. Then, the voltage drop value of each functional cell is used as the reference for each cell row, thereby optimizing the wiring width of the power supply and the width of the cell rows.

According to the invention of the JP-A-2002-31392910, the supplied voltage is made to increase with respect to the reference supplied voltage by means of a boosting circuit, thereby keeping the voltage drop in the area of an internal integrated circuit within the allowable designed range.

However, the following drawbacks are known in related art:

(1) In the case in which the number of power supply wirings within the internal integrated circuit, it is impossible to provide pins in the area used as the power supply wiring, leading to a disadvantage in that the size of a semiconductor chip becomes larger. (2) As for the increased number of power supply pins, the possible assigned number thereof is limited in the case of the semiconductor integrated circuit having a large number of signal pins, so it cannot help but make the size of a semiconductor chip larger.

(3) In the case in which the voltage drop is checked and the power enhancement is performed after the automated placement and routing, it is needed to redesign if the number of power supply pins is not sufficient. In such case, the time necessary for development (TAT) cannot be shortened.

(4) According to the invention disclosed in the JP-A-2000-20576, it is true that the wiring width of the power supply can be optimized. However, this optimization of the wiring width of the power supply cannot help but be disadvantageously performed within the internal integrated circuit.

(5) According to the invention of the JP-A-2002-313929, a new boosting circuit must be added for the power enhancement.

### SUMMARY

An advantage of the present invention is to provide a semiconductor integrated circuit and a method for designing the same with the view to power enhancement by utilizing an I/O area instead of an internal integrated circuit so as not to exert any disadvantage effect on the size of a semiconductor chip.

According to a first aspect of the invention, a semiconductor integrated circuit according to the invention includes: a semiconductor chip; an internal integrated circuit area formed at a center side of the semiconductor chip; and an I/O area formed at a peripheral side of the semiconductor chip except where the internal integrated circuit area exists, the I/O area having a first power supply cell placed at a predetermined position therein. In the case of existence of an empty area adjacent to the first power supply cell, a second power supply cell is inserted therein and the first power supply cell and the second power supply cell are electrically connected with each other by a first wiring pattern added.

According to a second aspect of the invention, a semiconductor integrated circuit includes: a semiconductor chip; an internal integrated circuit area formed at a center side of the semiconductor chip; an I/O area formed at a peripheral side of the semiconductor chip except where the internal integrated circuit area exists; a first power supply cell placed at a predetermined position within the I/O area; a second power supply cell to be inserted in an empty area adjacent to the first power supply cell; and a first wiring pattern allowing the first power supply cell and the second power supply cell to be electrically connected with each other.

In this case, the first power supply cell may be electrically connected with a predetermined power supply pin by a predetermined second wiring pattern.

It is preferable that the first wiring pattern allow a pin connecting portion of the first power supply cell and a corresponding pin connecting portion of the second power supply cell to be electrically connected with each other and being partially electrically connected with the second wiring pattern.

In this case, the first wiring pattern may be electrically connected with a pin connecting portion of the second power supply cell along an entire extension in a length direction of the pin connecting portion of the second power supply cell, and having an allowable width in a length direction at the pin connecting portion.

According to a third aspect of the invention, a method for designing a semiconductor integrated circuit including an internal integrated circuit area formed at a center side of a semiconductor chip and an I/O area formed at a peripheral side of the semiconductor chip except where the internal integrated circuit area exists, includes: inserting, in a case where an empty area exists in an area adjacent to a first power cell provided at a predetermined position within the I/O area, a second power cell in the empty area; and adding a wiring pattern to electrically connect the second power supply cell inserted and the first power supply cell with each other.

In this case, the first power supply cell may be electrically connected with a predetermined power supply pin by a predetermined wiring pattern in advance.

According to the invention as thus described above, instead of the area of the internal semiconductor circuit the empty area of the I/O area, for example, is used, so it is possible to achieve power enhancement while exerting no adverse effect on the size of the semiconductor chip.

Further, according to the invention, it is possible to achieve power enhancement without involving increase in number of power supply pins, for example.

### BRIEF DESCRIPTION OF THE DRAWINGS

The invention will be described with reference to the accompanying drawings, wherein like numbers reference like elements.

FIG. 1 is a partially enlarged schematic view of a semiconductor integrated circuit according to a method for designing according to the invention, showing the state in which the power has not been enhanced yet.

FIG. 2 is a partially enlarged plan view of the semiconductor integrated circuit of FIG. 1 showing the state in which the power has been enhanced.

FIG. 3 is a flow chart showing an example of procedures of a method for designing according to the invention.

FIG. 4 is a partially enlarged schematic view of another construction example of the semiconductor integrated circuit according to the method of the invention.

FIG. 5 is a partially enlarged schematic view of yet another construction example of the semiconductor integrated circuit according to the method of the invention.

### DESCRIPTION OF EXEMPLARY EMBODIMENTS

Hereinafter, embodiments of the invention will be described with reference to the accompanying drawings.

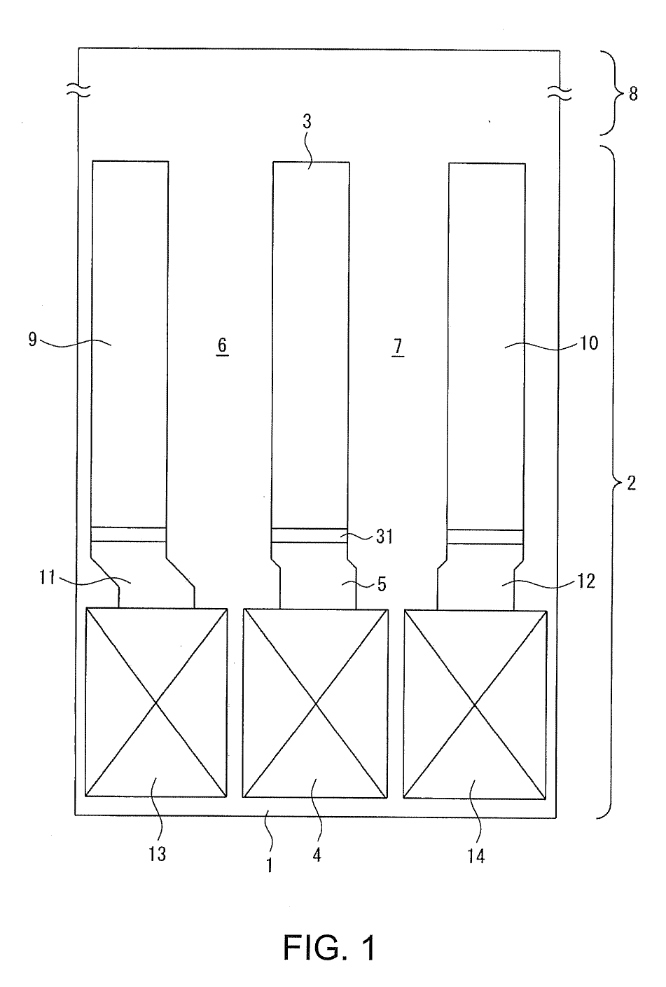

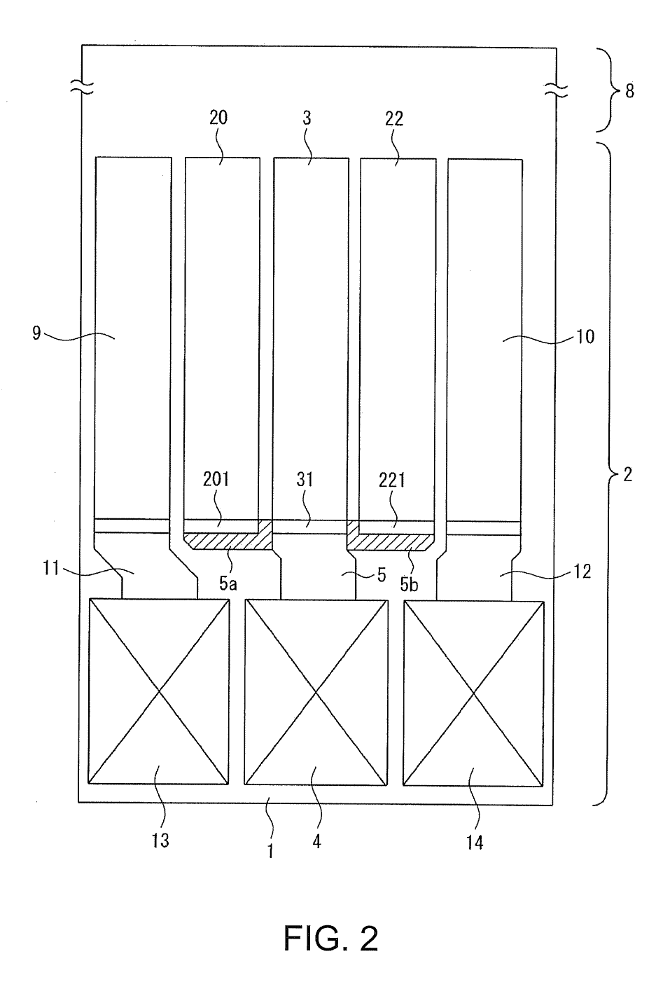

First, the outline of the method for designing a semiconductor integrated circuit according to the invention and concrete examples of the semiconductor integrated circuit manufactured according to this method will be described with reference to FIG. 1 and FIG. 2.

According to this method, for layout design of the semiconductor integrated circuit, the designer should check a power supply cell placed beforehand at a determined position within an input/output area (I/O area) of a semiconductor chip, and at the same time check (verify) on the display screen of a computer whether the areas adjacent to this power supply cell are empty areas (empty slots) or not.

FIG. 1 is a partially enlarged schematic view of the semiconductor integrated circuit according to the method of the invention showing the state in which the power has not been enhanced yet.

In this semiconductor integrated circuit, a predetermined power supply cell 3 is placed within an I/O area 2 of a semiconductor chip 1. A pin connecting portion 31 of the power supply cell 3 and a power supply pin (power supply pad) placed at a predetermined are electrically connected with each other by a wiring pattern 5. Two empty areas 6, 7 are adjacent to the right and left sides of the power supply cell 3. Therefore, the designer should check at the time of layout design whether there are empty areas 6, 7 in the areas adjacent to the power supply cell 3.

Here, the power supply cell is a predetermined unit cell that supplies an internal semiconductor integrated circuit (not shown) placed at the center of semiconductor chip 1, I/O cells 9, 10 and so on with power. Further, the empty area is an area having no function as power supply cell or I/O cell, in which a new power supply cell etc can be placed and inserted.

In the semiconductor integrated circuit shown in FIG. 1, an internal semiconductor integrated circuit 8 is placed at the center of the semiconductor chip 1 and the I/O area 2 is placed at the peripheral side of the semiconductor chip 1 except where this internal semiconductor integrated circuit 8 is placed. Furthermore, the I/O cells 9, 10 are placed to be adjacent to the empty areas 6, 7 within the I/O area 2. The I/O cells 9, 10 are electrically connected to corresponding signal pins (signal pads) 13, 14 through the intermediation of wiring patterns 11, 12.

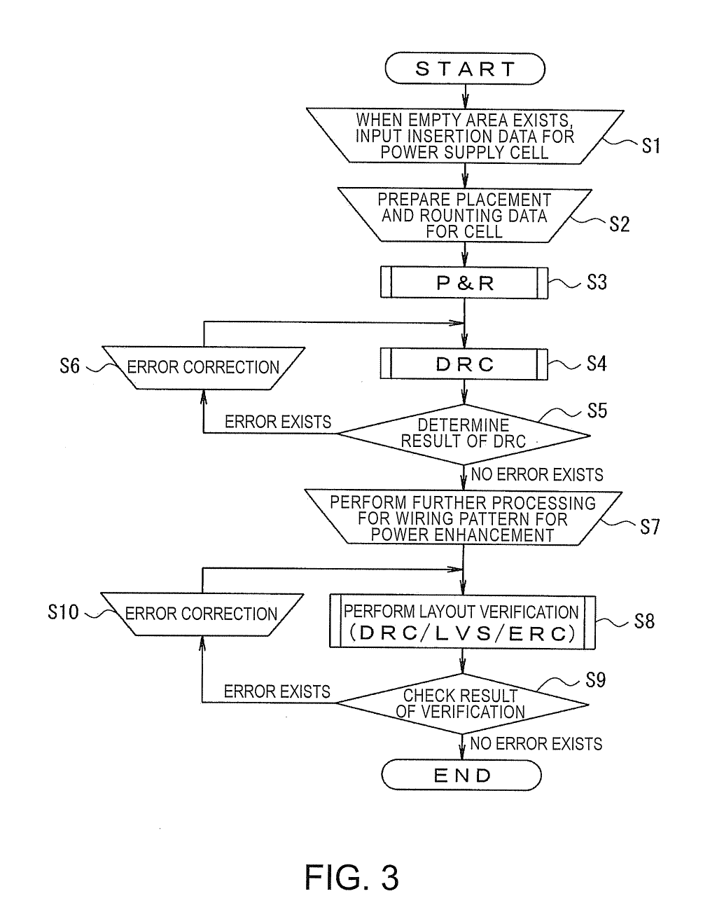

At the time of layout design, when the designer has confirmed that there are the empty areas 6, 7 in the areas adjacent to the power supply cell 3, as shown in FIG. 1, the designer should perform such processing on the display screen of the computer that new power supply cells 20, 22 shown in FIG. 3 are to be inserted (placed) in the empty areas 6, 7.

In conjunction with insertion of those power supply cells 20, 22, the designer should perform the further processing on the display screen of the computer for layout design to electrically connect the power supply cells 20, 22 and the power supply cell 3 with each other, as shown in FIG. 2.

According to the method for designing described above, as shown in FIG. 2, the semiconductor integrated circuit with enhanced power can be obtained.

In the semiconductor integrated circuit shown in FIG. 2, the power supply cells 20, 22 are inserted in the empty area at the right and left sides of the power supply cell 3, and the power supply cell 3 and the power supply cells 20, 22 are electrically connected with each other through the intermediation of wiring patterns 5a, 5b added (inserted). Furthermore, the power supply cell 3 is electrically connected with the power supply pin 4 through the intermediation of the wiring pattern 5.

To be more specific, the wiring patterns 5a, 5b added allow a pin connecting portion 31 of the power supply cell 3 and its corresponding pin connecting portions 201, 221 of the power supply cells 20, 22 to be electrically connected with each other and are themselves electrically connected with a part of the wiring pattern 5.

The wiring pattern 5 added is electrically connected with the pin connecting portion 201 of the power supply cell 20 while being inserted in the entire extension in the length direction of the pin connecting portion 201. The wiring pattern 5a has an allowable width in the position corresponding to the length direction (lateral direction shown in FIG. 3) of the pin connecting portion 201 out of the connecting area of the wiring pattern 5a and the pin connecting portion 201. Here, the allowable width means the width allowing for wiring physically and electrically, for example.

Likewise, the wiring pattern 5b added is electrically connected with the pin connecting portion 221 of the power supply cell 22 while being inserted in the entire extension in the length direction of the pin connecting portion 221. The wiring pattern 5b has an allowable width in the position corresponding to the length direction (lateral direction shown in FIG. 3) of the pin connecting portion 221 out of the connecting area of the wiring pattern 5b and the pin connecting portion 221.

Next, the method for designing the semiconductor integrated circuit according to this embodiment of the invention will be described with reference to the flow chart shown in FIG. 3.

Of the design of the semiconductor integrated circuit, this embodiment relates to layout design, which is performed with the aid of computer. In this stage, the circuit design before the layout design, for example, has been already completed and various data necessary for the layout design (for example, a net list, pin information and so on) and soft wares, which are necessary tools for the design thereof should be stored in the memory device.

First, in the step S1, the net list (circuit connection information) and pin information are displayed on the display screen of a display device. The designer references the net list and pin information shown on the display screen and checks the power supply cell placed within input/output area (I/O area) of the semiconductor chip of the display device.

At the same time of this, the designer checks (verifies) whether there are empty areas (empty slots) in the areas adjacent to the power supply cell. As the result of this check, when it is verified that there are empty areas, the designer inputs from an input device data (pin information) for insertion (placement) of new power supply cell in those empty areas.

In the step S2, placement and routing data of cell is prepared. Following this, placement and routing processing (P&R) for each cell is performed based on the placement and routing data of cell and added data (step S3). After this, design rule check (DRC) is performed to check whether the graphics inputted (generated) by this processing predetermined rules fulfill or not (step S4).

In the step S5, regarding the result of the design rule check, it is determined whether there is any error. When as the result of this determination it has been confirmed that there is an error, the iterative process of performing error correction in the step S6 and returning to the step S4 should be performed until no more error will exist. When error does not exist any more, the process proceeds to the next step S7.

In the step S7, in order to achieve power enhancement by electrically connecting the predetermined power supply cell and the cells inserted (added) in the empty areas with each other, the designer performs by using the input device further processing of the wiring patterns for this power enhancement while looking at the display screen. Data that identify the wiring data added, for example, data on connecting position or connecting width are recognized by computers.

As thus the layout process has been completed, in the step S8, the verification of this layout is carried out. This verification includes the above-mentioned design rule check (DRC), the check whether the layout corresponds to the schematic (LVS) and the check as to electrical connection (ERC).

In the step S9, regarding the result of the layout verification, it is determined whether there is any error. When as the result of this determination it has been confirmed that there is an error, the routine of performing error correction in the step S10 and returning to the step S8 should be repeatedly performed until no more error will exist. When error does not exist any more, the series of steps are to be completed.

According to such method for designing consisting of the series of steps described above, it is possible to manufacture the semiconductor integrated circuit shown in FIG. 2.

Note that in FIG. 3 the processes in the steps S1 through S6 are carried out by using an automated placement and routing tools, the process in the step S7 is performed by using a layout creating tool and the processes in the steps S8 through S10 are executed by using a layout verification tool.

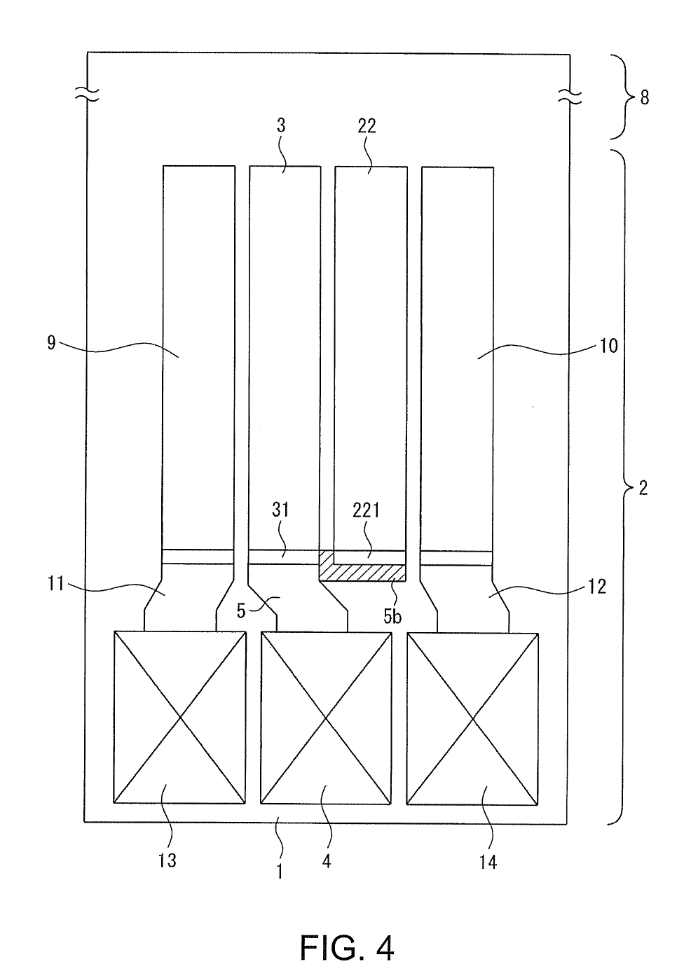

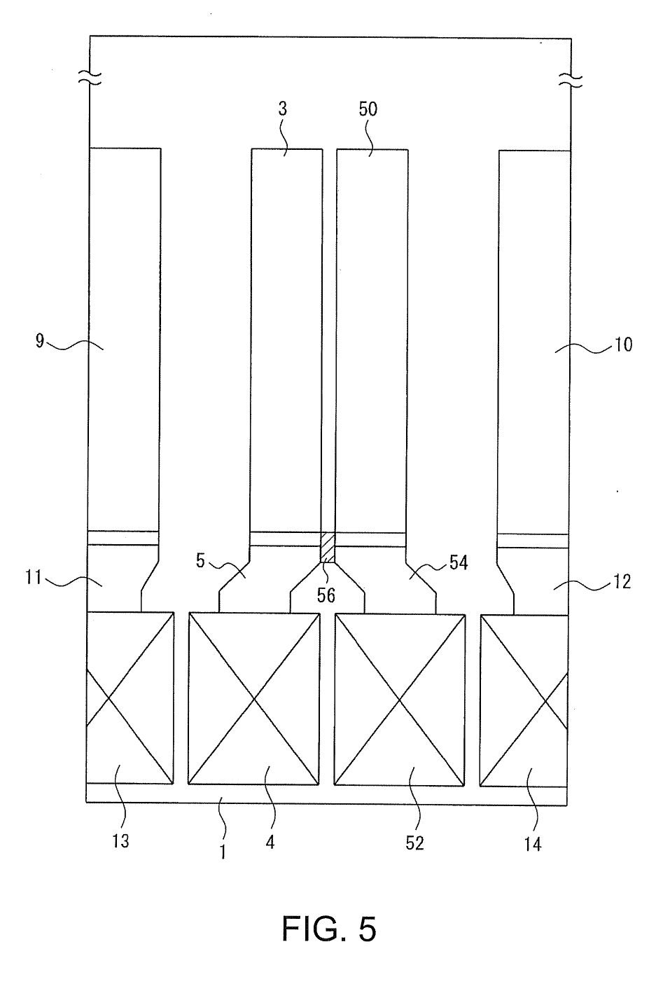

Then, other construction examples of the semiconductor integrated circuit fabricated in accordance with the method for designing according to the invention will be described with reference to FIG. 4 and FIG. 5.

In the semiconductor integrated circuit shown in FIG. 4, of the areas adjacent to the power supply cell 3, only right area includes an empty area, in which the power supply cell 22 is to be inserted. In accordance with this, the wiring pattern 5b is added in order to electrically connect the power supply cell 3 and the power supply cell 22 with each other.

In the semiconductor integrated circuit shown in FIG. 5, in addition to the power supply cell 3, a power supply cell 50 has also been placed beforehand. Here, when the power supply cells 3, 50 and the power supply pins 4, 52 are electrically connected with each other beforehand by the corresponding wiring patterns 5, 54, the wiring pattern 56 is added in order to establish the electrical connection between those power supply cells 3, 50, as shown in the drawing.

As thus constructed, it is possible to use the power supply pins 4, 52 as one power supply pin without establishing direct common connection between the power supply pins 4, 52.

As thus described above, according to the embodiment of the invention, power enhancement is to be achieved not within the area of the internal semiconductor integrated circuit but in the I/O area. Therefore, it is possible to enhance power without imparting any influence on the size of the semiconductor chip.

Furthermore, according to the embodiment of the invention, in the case in which the area adjacent to the power supply cell placed beforehand is empty area, a further power supply cell is to be inserted in the empty area, and in conjunction with this insertion, a wiring pattern is to be added in order to electrically connect the power supply cells with each other. As a result, it is possible to enhance power without involving increase in the number of power supply pins.

Moreover, the method of designing in accordance of the invention can be easily performed by utilizing related art design tools. Yet further, since there have been taken the provisions for power enhancement before automated placement and routing, voltage drop can be prevented.

What is claimed is:

1. A semiconductor integrated circuit, comprising:
an internal integrated circuit area formed at a center side of a semiconductor chip; and
an I/O area formed at a peripheral side of the semiconductor chip except where the internal integrated circuit area exists, the I/O area having a first power supply cell placed at a predetermined position therein, in a case in which an empty area adjacent to the first power supply cell exists, a second power supply cell being inserted therein and the first power supply cell and the second power supply cell being electrically connected with each other by a first wiring pattern.

2. A semiconductor integrated circuit, comprising:
an internal integrated circuit area formed at a center side of a semiconductor chip;
an I/O area formed at a peripheral side of the semiconductor chip except where the internal integrated circuit area exists;
a first power supply cell placed at a predetermined position within the I/O area;
a second power supply cell to be inserted in an empty area adjacent to the first power supply cell; and
a first wiring pattern allowing the first power supply cell and the second power supply cell to be electrically connected with each other.

3. The semiconductor integrated circuit according to claim 1, the first power supply cell being electrically connected with a predetermined power supply pin by a predetermined second wiring pattern.

4. The semiconductor integrated circuit according to claim 1, the first wiring pattern allowing a pin connecting portion of the first power supply cell and a corresponding pin connecting portion of the second power supply cell to be electrically connected with each other, and being partially electrically connected with the second wiring pattern.

5. The semiconductor integrated circuit according to claim 1, the first wiring pattern being electrically connected with a pin connecting portion of the second power supply cell along an entire extension in a length direction of the pin connecting portion of the second power supply cell, and having an allowable width in a length direction at the pin connecting portion.

6. A method for designing a semiconductor integrated circuit including an internal integrated circuit area formed at a center side of a semiconductor chip and an I/O area formed at a peripheral side of the semiconductor chip except where the internal integrated circuit area exists, the method comprising:
inserting, in a case where an empty area exists in an area adjacent to a first power cell provided at a predetermined position within the I/O area, a second power cell in the empty area; and
adding a wiring pattern to electrically connect the second power supply cell inserted and the first power supply cell with each other.

7. The method for designing a semiconductor integrated circuit according to claim 6, the first power supply cell being electrically connected with a predetermined power supply pin by a predetermined wiring pattern in advance.

8. An I/O cell area; comprising:
a first power supply cell;
a first pin;
a first wiring that connects the first power supply cell and the first pin;
a second power supply cell; and
a second wiring that connects the first power supply cell and the second power supply cell.

9. The I/O cell area according to claim 8, further comprising:
a third power supply cell; and
a third wiring that connects the first power supply cell and the third power supply cell,
the first power supply cell being disposed between the second power supply cell and the third power supply cell.

10. The I/O cell area according to claim 8,
the first pin being disposed in a first direction of the first power supply cell,
the second power supply cell being disposed in a second direction of the first power supply cell,
the first direction being orthogonal to the second direction,
the first wiring having a first outer edge disposed on a side of the first power supply cell,
the first wiring having a second outer edge disposed on a side of the first pin, and
a center of the second outer edge of the first wiring being disposed in a side of the second direction of a center of the first outer edge of the first wiring.

11. The I/O cell area according to claim 8,
the first pin being disposed in a first direction of the first power supply cell,
the second power supply cell being disposed in a second direction of the first power supply cell,
the first direction being orthogonal to the second direction,
the first power supply cell having a first width that is a length of the second direction of the first power supply cell,
the second power supply cell having a second width that is a length of the second direction of the second power supply cell,
the first pin having a third width that is a length of the second direction of the first pin,
the third width is wider than the first width,
the third width is wider than the second width,
the third width is narrower than sum of the first width and the second width.
